(19) United States
(12) Patent Application Publication
(10) Pub. No.: US 2024/0155782 A1
(43) Pub. Date: May 9, 2024

(54) Housing Assembly For Encasing An Electromagnetic Component And A Method For Assembling A Housing

(71) Applicant: Tyco Electronics Austria GmbH, Vienna (AT)

(72) Inventors: Philipp Harrer, Waidhofen an der Thaya (AT); Markus Gutmann, Waidhofen an der Thaya (AT)

(73) Assignee: Tyco Electronics Austria GmbH, Vienna (AT)

(21) Appl. No.: 18/411,257

(22) Filed: Jan. 12, 2024

Related U.S. Application Data
(62) Division of application No. 16/788,746, filed on Feb. 12, 2020.

(30) Foreign Application Priority Data
Feb. 12, 2019 (EP) 19156562.1

(51) Int. Cl. H05K 5/00; H05K 5/02

(52) U.S. Cl. CPC H05K 5/0091; H05K 5/0208

(57) ABSTRACT

A housing assembly encasing an electromagnetic component includes a housing part, a bulkhead wall inserted into the housing part in an insertion direction, a locking sub-assembly locking the bulkhead wall to the housing part, and a glue transport channel formed between the bulkhead wall and the housing part. The housing part has a first wall section and a second wall section opposite the first wall section. The bulkhead wall extends from the first wall section to the second wall section in a horizontal direction in an inserted state in the housing part.

### CROSS-REFERENCE TO RELATED APPLICATION

This application is a divisional application of U.S. patent application Ser. No. 16/788,746, filed on Feb. 12, 2020, which claims the benefit of the filing date under 35 U.S.C. § 119(a)-(d) of European Patent application Ser. No. 19/156,562.1, filed on Feb. 12, 2019.

### FIELD OF THE INVENTION

The present invention relates to a housing assembly and, more particularly, to a housing assembly for encasing an electromagnetic component.

### BACKGROUND

A housing assembly encasing an electromagnetic component is often subjected to high inside pressure, which may occur due to high ambient and/or operating temperatures. Rapid temperature changes in combination with humidity inside the housing assembly may also increase the inside pressure. The inside pressure may deform and/or damage the housing.

### SUMMARY

A housing assembly encasing an electromagnetic component includes a housing part, a bulkhead wall inserted into the housing part in an insertion direction, a locking sub-assembly locking the bulkhead wall to the housing part, and a glue transport channel formed between the bulkhead wall and the housing part. The housing part has a first wall section and a second wall section opposite the first wall section. The bulkhead wall extends from the first wall section to the second wall section in a horizontal direction in an inserted state in the housing part.

### BRIEF DESCRIPTION OF THE DRAWINGS

The invention will now be described by way of example with reference to the accompanying Figure, of which:

FIG. 1 is a sectional top view of a housing assembly according to an embodiment;

FIG. 2 is a detail view of a portion of FIG. 1 in a dashed box;

FIG. 3 is a sectional top view of a locking sub-assembly according to an embodiment;

FIG. 4 is a sectional top view of a locking sub-assembly according to another embodiment;

FIG. 5 is a sectional top view of a locking sub-assembly according to another embodiment;

FIG. 6 is a perspective view of a further housing part according to an embodiment;

FIG. 7 is a perspective view of the housing assembly in an inserted state;

FIG. 8 is a detail view of a portion of FIG. 7 in a dashed circle; and

FIG. 9 is a sectional perspective view of the housing assembly in the inserted state.

### DETAILED DESCRIPTION OF THE EMBODIMENT(S)

Exemplary embodiments of the present invention will be described hereinafter in detail with reference to the attached drawings, wherein like reference numerals refer to like elements. The present invention may, however, be embodied in many different forms and should not be construed as being limited to the embodiments set forth herein. According to the description of the various aspects and embodiments, elements shown in the drawings can be omitted if the technical effects of those elements are not needed for a particular application, and vice versa: i.e. elements that are not shown or described with reference to the figures but are described above can be added if the technical effect of those particular elements is advantageous in a specific application.

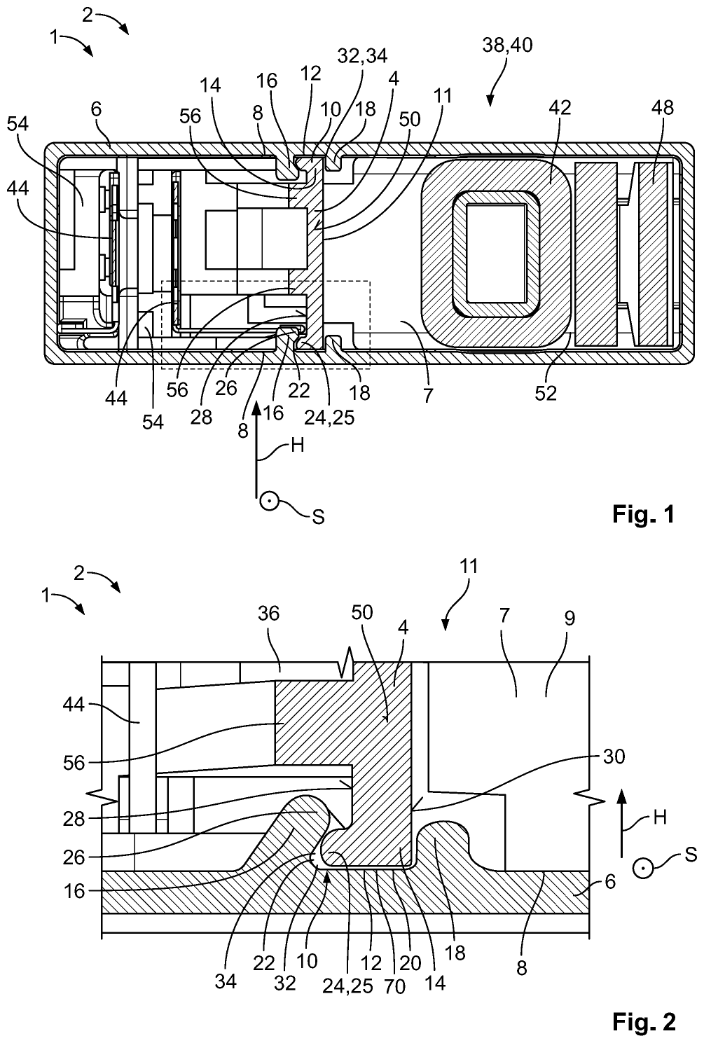

A housing assembly 1 according to an embodiment is shown in FIG. 1 in an inserted state 2, in which a bulkhead wall 4 is inserted in an insertion direction S into a housing part 6. In the inserted state 2, the bulkhead wall 4 extends from a first wall section 8 of the housing part 6 to a second wall section 8 of the housing part 6 opposite the first wall section 8 in a horizontal direction H. The horizontal direction H is arranged essentially perpendicular to the insertion direction S. The bulkhead wall 4 is arranged essentially perpendicular to the wall sections 8. The housing assembly 1 includes a locking sub-assembly 10 locking the bulkhead wall 4 to the housing part 6 in a direction essentially parallel to the horizontal direction H.

The bulkhead wall 4, as shown in FIG. 1, may be arranged in a central portion 11 of the housing part 6 in the inserted state 2, the central portion 11 being in a center of the housing part 6 perpendicular to the insertion direction S and the horizontal direction H. The central portion 11 is usually an area of the housing part 6 with a largest deformation resulting from a high inside pressure. Therefore, the bulkhead wall 4 may be arranged in the central portion 11 to prevent the deformation. However, depending on the size of the housing assembly 1, the bulkhead wall 4 may also be arranged in different portions or more than one bulkhead wall 4 may be provided distanced from one another perpendicular to the insertion direction S and horizontal direction H.

The locking sub-assembly 10, as shown in FIG. 1, has a rail guide 12 extending along the insertion direction S. The rail guide 12 is formed integrally with the wall section 8 and is adapted to engage a side edge 14 of the bulkhead wall 4. The rail guide 12 may be formed by a pair of ribs 16, 18 jutting out from the wall section 8 and extending along the insertion direction S, as shown in FIGS. 1 and 2. The two ribs 16, 18 may be distanced from one another perpendicular to the insertion direction S and horizontal direction H forming a notch 20 between them. The side edge 14 is adapted to be slidingly inserted into the notch 20. In the shown embodiment, each of the wall sections 8 has one rail guide 12 so that the bulkhead wall 4 may be engaged to the housing part 6 at both sides in the horizontal direction H. Hence, the locking sub-assembly 10 may comprise an engagement between bulkhead wall 4 and housing part 6 at either side in the horizontal direction H. Because the locking sub-assembly 10 comprises an essentially symmetric construction, the reference numerals are only shown on one of the two sides in FIGS. 1 and 2. In an embodiment, the housing part 6 is formed as an injection molded component, and the ribs 16, 18 are integrally formed with the housing part 6.

In order to form a positive interlock, at least one of the ribs 16 may form an undercut 22 in which a protrusion 24, e.g. a tongue 25 of the bulkhead wall 4 may be inserted in the inserted state 2, as shown in FIGS. 1 and 2. The undercut 22 may be formed by having the rib 16 extending obliquely from the wall section 8 towards the bulkhead wall 4. Alternatively, the rib 16 may comprise a protrusion 26 extending towards the bulkhead wall 4 and overlapping with the protrusion 24 in the horizontal direction H. The overlapping protrusions 24, 26 may form a positive fit blocking relative movement of the housing part 6 and bulkhead wall 4 at least parallel to the horizontal direction H. The rail guide 12 may also block movement of the housing part 6 and the bulkhead wall 4 perpendicular to the horizontal direction H and the insertion direction S.

One of the two ribs 16, 18 may comprise a higher material thickness than the other rib. In an embodiment, the rib 16 having the undercut 22 has a higher material thickness than the other rib 18; the rib 16 having the undercut 22 may be further stabilized and the locking sub-assembly 10 may compensate higher forces in the horizontal direction H.

The components of the locking sub-assembly 10 may be dimensioned to form a press-fit connection in the inserted state 2. In the embodiment shown in FIGS. 1 and 2, however, a gap 32 may be provided between the interlocking parts, i.e. the ribs 16, 18 of the rail guide 12 and the side edge 14 of the at least one bulkhead wall 4. The gap 32 may be filled with a glue 34, e.g. a sealing epoxy, adhesively bonding the interlocking parts to one another and further strengthening the locking sub-assembly 10. When the glue 34 is hardened, the locking sub-assembly 10 may in particular further lock relative movement in the insertion direction S.

The locking sub-assembly 10 thus transmits forces parallel to the horizontal direction H. In an embodiment, the rail guide 12 allows a relative sliding between the housing part 6 and the bulkhead wall 4 in the insertion direction S and blocks movement parallel to the horizontal direction H. The rail guide 12 may guide the insertion of the bulkhead wall 4 into the housing part 6 and further prevent a deformation of the housing part 6.

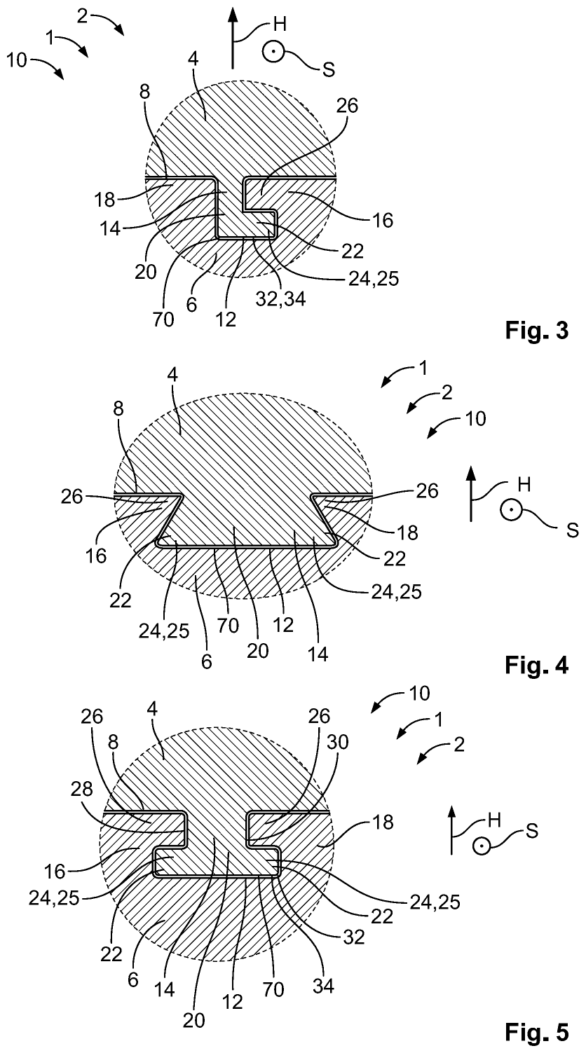

Other forms of the interlock between the bulkhead wall 4 and the housing part 6 are shown in FIGS. 3-5. The interlock may be L-shaped, T-shaped or dovetail-shaped. In particular, with a T-shaped or dovetail-shaped interlock, as shown in FIGS. 4 and 5, a front 28 and a back 30 of the bulkhead wall 4 may be engaged by the locking sub-assembly 10. Hence, a large overlapping surface area may be achieved, further strengthening the interlock. The locking sub-assembly 10 may also be further strengthened by adding the glue 34 as described above.

As shown in the embodiments of FIGS. 3-5, the rail guide 12 is formed on the housing part 6 and the bulkhead wall 4 has the complementary formed protrusion 24 adapted to be received in the inserted state 2. However, it should be noted that it could also be the other way around; in another embodiment, the side edge 14 of the bulkhead wall 4 could have the rail guide 12 and the housing part 6 a complementary formed protrusion 24 adapted to be received in the rail guide 12.

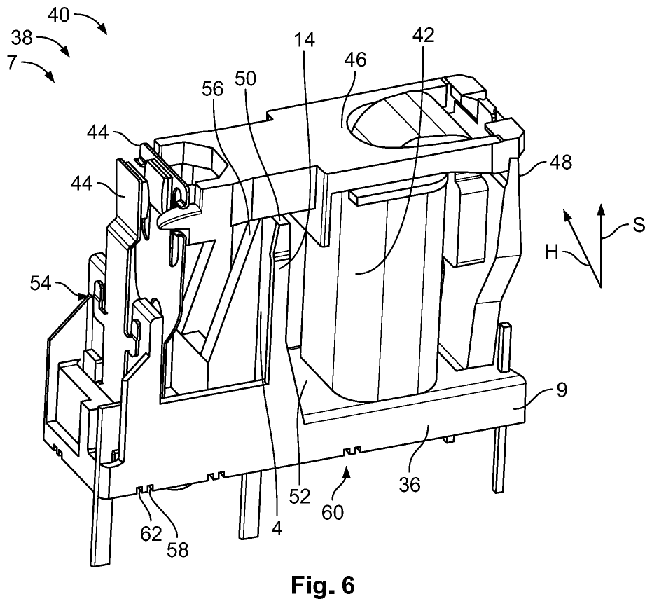

The bulkhead wall 4 may be part of a further housing part 7, as shown in FIGS. 1 and 2, adapted to be received in the housing part 6 in the inserted state 2. The further housing part 7, as shown in FIGS. 6-8, includes a base 9 adapted to close an opening 13 of the housing part 6 for receiving the bulkhead wall 4. The further housing part 7 and the bulkhead wall 4 may be formed integrally with one another as a monolithic component 36.

The further housing part 7, as shown in FIG. 6, may hold an electromagnetic component 38, particularly a relay 40. The relay 40 has an electromagnetic coil 42 and a pair of contact springs 44, which are arranged opposite to one another. One of the two contact springs 44 is connected to a drive element 46, which is further coupled to an armature 48 that is adapted to be moved by the electromagnetic coil 42. The drive element 46 thus moves the contact spring 44 towards the other contact spring 44 when the electromagnetic coil 42 is powered. The drive element 46 is arranged in the insertion direction S above the bulkhead wall 4 and extends from the armature 48 perpendicular to the insertion direction S and horizontal direction H to the contact spring 44. The drive element 46, in an embodiment, is distanced from a free end 50 of the bulkhead wall 4 so that the bulkhead wall 4 is not affected by the movement of the drive element 4.

The bulkhead wall 4, as shown in FIG. 6, is arranged at a central portion of the further housing part 7, separating a pair of chambers 52, 54. A first chamber 52 holds the electromagnetic coil 42 and the armature 48, while a second chamber 54 features the contact springs 44. The bulkhead wall 4 extends in the insertion direction S from the base 9. To further stabilize the bulkhead wall 4, a pair of stabilizing posts 56 are formed on a surface of the bulkhead wall 4 extending in the horizontal direction H. The stabilizing posts 56 are arranged distanced from one another in the horizontal direction H having an increased material thickness and taper towards the surface in the insertion direction S. The stabilizing posts 56 may prevent relative movement of the bulkhead wall 4 with respect to the further housing part 7 due to shock or vibrations, thus further increasing the strength of the bulkhead wall 4 and the reliability of the locking sub-assembly 10. The bulkhead wall 4 may close the housing assembly 1 in the inserted state 2, encasing the electromagnetic component 38.

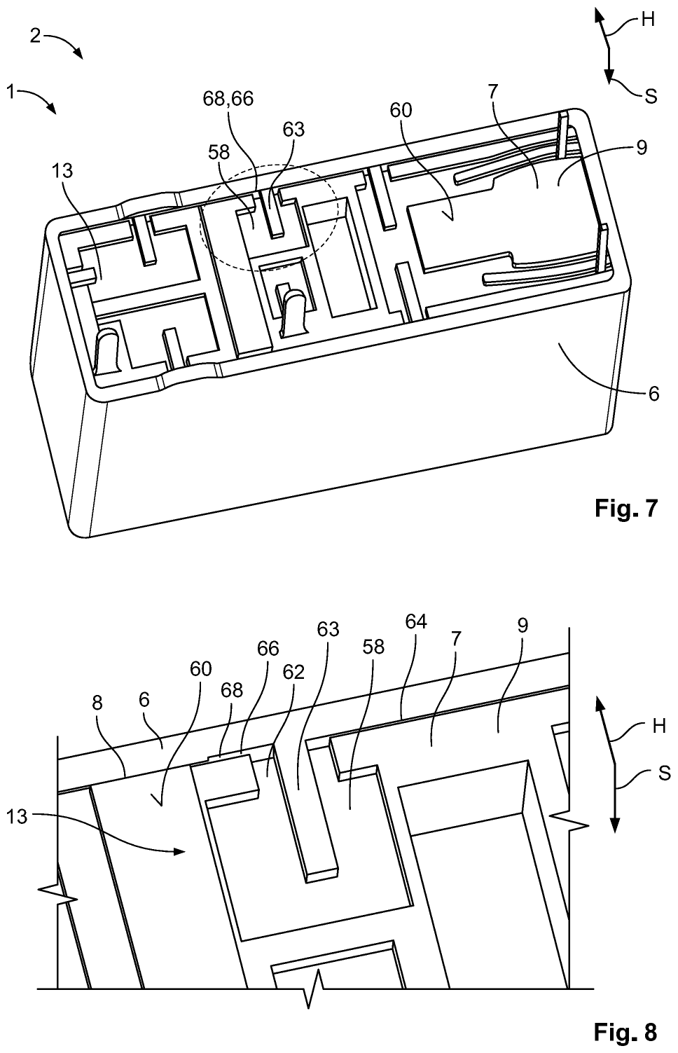

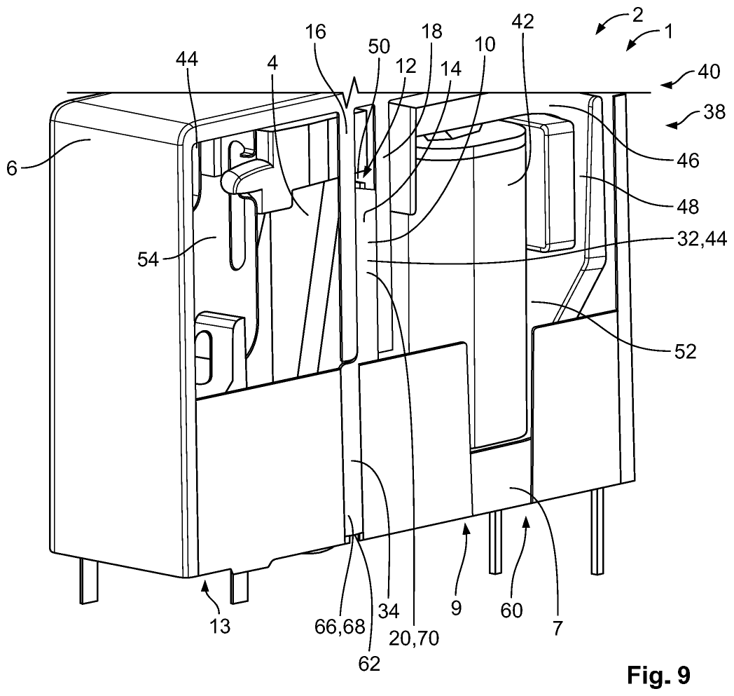

The further housing part 7, as shown in FIGS. 7 and 8, has a plurality of recesses 58 that are opened towards the outer circumference at the base 9. In FIG. 7, a bottom surface 60 facing away from the housing part 6 of the further housing part 7 is visible. A plurality of recesses 58 are formed on the bottom surface 60 of the further housing part 7. Each recess 58 has at least one furrow 62, shown in FIGS. 6 and 9, which opens towards the outer circumference of the bottom surface 60. The furrows 62 each border a guiding rib 63 for guiding glue 34 into the furrows 62. The recesses 58 and the guiding ribs 63, in an embodiment, have sharp edges, therefore acting as a capillary guiding the glue 34. In the inserted state 2, the furrows 62 open the inner circumference of the opening 13 of the housing part 6. Consequently, the furrows 62 are adapted to guide the glue 34 into slots 64 between the circumferences. By applying a sealing glue, e.g. a sealing epoxy, the housing assembly 1 may be hermetically sealed, creating an airtight housing assembly 1 and protecting the electromagnetic components 38 from water vapors and/or other foreign bodies.

As shown in FIG. 8, a groove 66 is formed on the wall section 8 of the housing part 6. In the inserted state 2, the furrow 62 of the recess 58 opens into the groove 66. The groove 66 comprises sharp edges and extends in the insertion direction S forming a glue transport channel 68. Due to the sharp edges, the glue may be sucked into the housing assembly 1 between the wall section 8 and the further housing part 7 in the inserted state 2, further sealing the housing assembly 1.

The housing assembly 1 is shown in the inserted state 2 in FIG. 9. The wall section 8 has been removed to allow insight into the inside of the housing assembly 1 in the inserted state 2. As shown in FIG. 9, the glue transport channel 68 is filled with glue 34. The glue transport channel 68 extends in the insertion direction S and abuts one of the ribs 16, 18. The abutting rib 16 redirects the glue 34 into the notch 20 of the rail guide 12. Thus, the locking sub-assembly 10 forms a further glue transport channel 70 that continues the glue transport channel 68. The further glue transport channel 70 is bordered by the ribs 16, 18 and extends in the insertion direction S. The glue transport channel 68 and the further glue transport channel 70 may be arranged in planes parallel to one another and be arranged in a staggered formation in the insertion direction S. Therefore, the glue 34 may be sucked between the side edge 14 of the bulkhead wall 4 and the rail guide 12, particularly via capillary action. In another embodiment, the glue 34 may also be transported through the glue transport channel 68 and/or the further glue transport channel 70 by pushing the glue 34 through the channel 68, 70 with pressure, e.g. air pressure.

In an embodiment, the glue 34 may be filled into the glue transport channel 68 and/or the further glue transport channel 70 before the insertion of the bulkhead wall 4. However, the glue 34 may solidify too quickly or may be displaced during the insertion, creating a non-uniform adhesive layer between the at least one bulkhead wall 4 and the housing part 6. Hence, the glue 34 may be filled into the glue transport channel 68 and/or the further glue transport channel 70 after insertion of the bulkhead wall 4 into the housing part 6.

The locking sub-assembly 10 counteracts an expansion of the housing part 6 in the horizontal direction H, due to occurring high inside pressure in the housing assembly 1. In particular, in hermetically sealed housing assemblies 1, the locking sub-assembly 10 reduces the shear-off forces on the sealing material significantly. Therefore, the inventive housing assembly 1 is more reliable and has a high durability.

What is claimed is:

1. A housing assembly encasing an electromagnetic component, comprising:
a housing part having a first wall section and a second wall section opposite the first wall section;
a bulkhead wall inserted into the housing part in an insertion direction and extending from the first wall section to the second wall section in a horizontal direction in an inserted state in the housing part;
a locking sub-assembly locking the bulkhead wall to the housing part; and
a glue transport channel formed between the bulkhead wall and the housing part in the inserted state.

2. The housing assembly of claim 1, wherein the glue transport channel is filled with a glue that hermetically seals the housing assembly.

3. The housing assembly of claim 2, wherein the glue is a sealing epoxy.

4. The housing assembly of claim 1, wherein the glue transport channel is a groove on one of the first wall section and the second wall section.

5. The housing assembly of claim 1, wherein the locking sub-assembly forms a further glue transport channel in the inserted state, the further glue transport channel is connected to the glue transport channel.

6. The housing assembly of claim 5, wherein at least one of the glue transport channel and the further glue transport channel is filled with a glue.

7. The housing assembly of claim 6, wherein the locking sub-assembly has a pair of overlapping protrusions overlapping in the horizontal direction.

8. The housing assembly of claim 7, wherein the glue is positioned between the overlapping protrusions.

9. The housing assembly of claim 4, further comprising a further housing part connected to the bulkhead wall.

10. The housing assembly of claim 9, wherein the further housing part has a base closing an opening of the housing part.

11. The housing assembly of claim 9, wherein the bulkhead wall and the further housing part are formed integrally with one another as a monolithic component.

12. The housing assembly of claim 9, wherein the further housing part has a plurality of recesses on a bottom surface, each of the recesses has a furrow that opens toward an outer circumference of the bottom surface.

13. The housing assembly of claim 12, wherein the furrow borders a guiding rib of the further housing part and guides a glue into a slot between the housing part and the further housing part.

14. The housing assembly of claim 12, wherein the furrow opens into the groove of the glue transport channel.

15. A method for assembling a housing for an electromagnetic component, comprising:
inserting a bulkhead wall in an insertion direction into a housing part;
locking the bulkhead wall to the housing part in a direction perpendicular to the insertion direction to form a housing assembly; and
filling a glue transport channel of the housing assembly with a glue.

16. The method of claim 15, wherein the glue transport channel is formed between the bulkhead wall and the housing part.

17. The method of claim 16, wherein the glue transport channel extends to a locking sub-assembly that locks the bulkhead wall to the housing part.

18. The method of claim 15, wherein the glue enters the glue transport channel by a capillary action.

19. The method of claim 15, wherein the glue is filled in the glue transport channel before the bulkhead wall is inserted into the housing part.

20. The method of claim 15, wherein the glue is filled in the glue transport channel after the bulkhead wall is inserted into the housing part.
